(19) United States
(12) Patent Application Publication
(10) Pub. No.: US 2018/0323398 A1
(43) Pub. Date: Nov. 8, 2018

(54) ORGANIC LIGHT EMITTING DIODE ASSEMBLY, MANUFACTURING METHOD THEREOF, AND DISPLAY PANEL

(71) Applicant: Shenzhen China Star Optoelectronics Technology Co. , Ltd., Shenzhen, Guangdong (CN)

(72) Inventors: Yunan ZHANG, Shenzhen, Guangdong (CN); Ting SHI, Shenzhen, Guangdong (CN)

(73) Assignee: Shenzhen China Star Optoelectronics Technology Co., Ltd., Shenzhen, Guangdong (CN)

(21) Appl. No.: 15/552,779

(22) PCT Filed: Jun. 22, 2017
(86) PCT No.: PCT/CN2017/089461

§ 371 Date: Aug. 22, 2017

(30) Foreign Application Priority Data
May 2, 2017 (CN) 201710302070.6

(51) Int. Cl. H01L 51/50; H01L 51/56; H01L 51/52

(52) U.S. Cl. CPC H01L 51/5076; H01L 51/56; H01L 51/0005; H01L 2251/5369; H01L 51/5206

(57) ABSTRACT

The present invention mainly provides an organic light emitting display assembly, a manufacturing thereof, and a display panel. The organic light emitting diode assembly comprises an anode layer, an electron hole transport layer, a light emitting layer, an electron transport layer, and a cathode layer arranged sequentially, wherein the anode layer is a metal layer with a high-power function, and the electron transport layer comprises a quantum dot material. By the above-mentioned method, the present invention can improve the stability of the electrode, thereby extending the life of OLED devices, and the color gamut of the OLED display can be improved.

### FIELD OF THE INVENTION

The present invention relates to a technology of organic light emitting display panel, and more particularly, to an organic light emitting display assembly, manufacturing thereof, and display panel.

### DESCRIPTION OF PRIOR ART

Organic Light Emitting Diodes (OLED) as a new generation of flat panel display devices, with advantages such as self-luminous, wide viewing angle, high contrast, fast response, low power consumption, is expected to become the next generation of mainstream flat panel display technology, and is one of the most watched technologies in flat panel display technology. The inventor of the present invention has found that the OLED device in the prior art has problems that the color gamut is low, the stability is poor, and the lifetime is short.

### SUMMARY OF THE INVENTION

The present invention mainly provides an organic light emitting display assembly, a manufacturing thereof, and a display panel to the technical problem, it can improve the color gamut and stability of OLED devices, and extend the life of OLED devices.

In order to solve the above-mentioned technical problems, a technical solution adopted by the present invention is to provide a method of manufacturing an OLED assembly, which comprising: forming a cathode layer on a substrate; forming an electron transport layer comprising a quantum dot material by the ink jet printing method, on the side of the cathode layer against the substrate; forming a light emitting layer on the side of the electron transport layer against the cathode layer; forming an electron hole transport layer on the side of the electron transport layer against the cathode layer; forming a metal layer with a high-power function as an anode layer by the vacuum deposition method, on the side of the electron hole transport layer against the cathode layer.

In order to solve the above-mentioned technical problems, another technical solution adopted by the present invention is to provide an OLED assembly, which comprising an anode layer, an electron hole transport layer, a light emitting layer, an electron transport layer, and a cathode layer arranged sequentially; wherein the anode layer is a metal layer with a high-power function; and wherein the electron transport layer comprises a quantum dot material.

In order to solve the above-mentioned technical problems, another technical solution adopted by the present invention is to provide an OLED display panel, which comprising: the above-mentioned OLED assembly.

The present invention can be concluded with the following advantages, the OLED assembly provided by the present invention is different from the prior art that the OLED assembly selects a metal layer with a high-power function as the anode layer, these metals with a high-power function have low chemical activity, can improve the stability of the electrode, thereby extending the life of OLED devices. In addition, the electron transport layer of the OLED assembly is doped with a quantum dot material, and the emission spectrum of the quantum dot light emitting material is concentrated, and the color purity is high, and the color gamut of the OLED display can be improved.

### BRIEF DESCRIPTION OF DRAWINGS

FIG. 1 is a structural illustration of an embodiment in accordance to an organic light emitting assembly in the present invention;

FIG. 2 is a structural illustration of an embodiment in accordance to an organic light emitting display panel in the present invention;

FIG. 3 is a structural illustration of an embodiment in accordance to an electronic equipment in the present invention; and

FIG. 4 is a flow chart of method of manufacturing an OLED assembly of an embodiment in the present invention.

### DESCRIPTION OF PREFERRED EMBODIMENT

Technical implementation will be described below clearly and fully by combining with drawings made in accordance with an embodiment in the present invention.

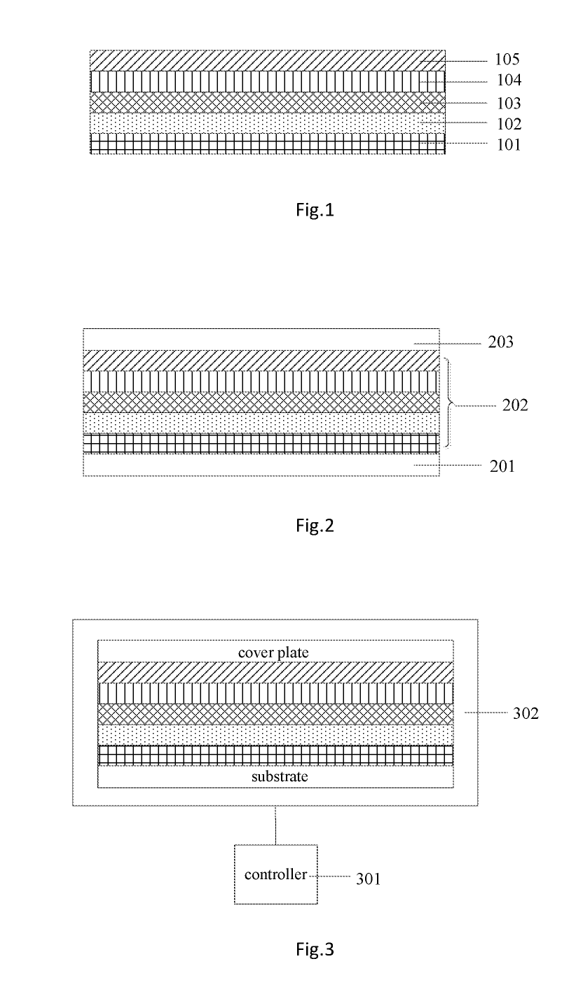

Referring to FIG. 1, FIG. 1 is a structural illustration of an embodiment in accordance to an organic light emitting assembly in the present invention. The OLED assembly of the embodiment comprises an anode layer 105, an electron hole transport layer 104, a light emitting layer 103, an electron transport layer 102, and a cathode layer 101 arranged sequentially, wherein the anode layer 105 is a metal layer with a high-power function, and the electron transport layer 102 comprises a quantum dot material.

OLED display driver is divided into passive matrix driving (PM-OLED) and active matrix driving (AM-OLED); active matrix driving is divided into amorphous silicon thin film transistor (a-Si TFT) technology and low temperature polysilicon thin film transistor (LTPS TFT) technology; and TFT is divided into p-type TFT and n-type TFT, wherein the p-type TFT provides electron holes to OLED device via drain electrode, which is connected to anode of the OLED, and the n-type TFT provides electrons to OLED device via drain electrode, which is connected to cathode of the OLED.

In the active matrix driving, the TFT that controls OLED is usually made on the side anode, so that the TFT must be required to be p-type. However, although the a-Si TFT has a simple and fully developed manufacturing process, because the charge carrier mobility in a-Si is very low and its hole mobility is much lower than charge carrier mobility, therefore, the a-Si TFT can only be made into n-type TFT, further limiting the application of a-Si TFT in OLED device. If want to choose to use the n-type TFT to control an OLED, in order to ensure that it works in the saturation zone, the OLED device must be connected to the drain of n-type TFT, that is, the cathode of the OLED device is connected to the drain of the n-type TFT, i.e., the OLED device has an inverted structure with a bottom electrode as a cathode. The use of OLED device with inverted structure can make the n-type TFT with superior performance to be used in AM-OLED pixel circuit, the choice of AMOLED drive circuit design is increased, and cost is reduced. The OLED device with inverted structure can be made into the top emitting device that emitting from the top and the bottom emitting device that emitting from the bottom.

In the general structure of the OLED device, the indium tin oxide (ITO) glass is often used as the anode. However, in the device with inverted structure, it is generally to choose metal electrodes to be used as the anode, existing OLED devices generally use the metals with low-power function (such as magnesium, calcium, lithium, cesium) as the electrode, but the chemical activity of these metals is high, making the device performance to be degraded failure easily, and the difficult of controlling mass production process of the OLED device is increased.

In one embodiment, the cathode of the OLED assembly of the present invention is a bottom electrode close to the substrate, i.e., the OLED assembly uses an inverted structure that the bottom electrode is a cathode, and choosing a metal layer with a high-power function to be used as the anode layer 105, e.g., gold (Au), silver (Ag), platinum (Pt), copper (Cu), iridium (Ir), or a mixture of the above metals, the chemical activity of these metals is relatively low, and the stability of electrodes of the OLED device can be improved, it can be further beneficial to improve the stability and service life of OLED devices

When the bulk phase of the semiconductor material gradually reduced to a certain critical size (1^{˜}20 nm), the carrier's volatility becomes significant, and its motion will be limited, resulting in an increase in kinetic energy, the corresponding electronic structure changes from a continuous energy level structure to a continuous quasi-split, the phenomenon is known as a quantum size effect. Quantum Dot (QD) is a particle material with the three-dimensional size in nano order, which follows the quantum size effect, i.e., the property of QD varies regularly with size. For example, the emission spectrum of QD is mainly controlled by the particle size of QD, and the emission spectrum can be adjusted by changing the particle size of QD. Therefore, the QD luminescent material has the advantages of high spectral concentration and high color purity.

In one embodiment, the electron transport layer 102 in the OLED assembly of the present invention is doped with a QD material, using its spectral concentration, high color purity performance, it can greatly improve the color gamut of OLED display.

Wherein the material of the QD may be QD material in the Groups II-VI, QD material in the Group III-V, an QD material in the Group I-III-VI, or a mixture of different QD materials. Wherein the QD material in the Groups II-VI refers to a compound which formed by the elements of Group II and the elements of Group VI, the QD material in the Group III-V and the QD material in the Group I-III-VI are the same. Specifically, the QD material may be one or more of ZnCdSe₂, CdSe, CdTe, CuInS₂, ZnCuInS₃.

In one embodiment, nanoparticles of zinc oxide (ZnO) or titanium oxide (TiOx) may be used as the material of the electron transport layer 102; the mass content of the QD material in the electron transport layer 102 is greater than 0 and less than or equal to 20%, e.g., 0.5%, 5%, 10%, 15%, 20%, and so on.

Preferably, in other embodiments, the OLED assembly of the present invention further comprises a hole injection layer, an electron injection layer, and so on.

Referring to FIG. 2, FIG. 2 is a structural illustration of an embodiment in accordance to an OLED display panel in the present invention. The OLED display panel of the embodiment comprises: a substrate 201, a cover plate 203, and an OLED assembly 202 located between the substrate 201 and the cover plate 203. Wherein the structure of the OLED assembly 202 is the same as that in the above embodiment, therefore no additional description is given herebelow. The OLED display panel is used for head-mounted display, MP3 display, TV, mobile phone display and so on.

Referring to FIG. 3, FIG. 3 is a structural illustration of an embodiment in accordance to an electronic equipment in the present invention. The electronic equipment of the embodiment comprises: a controller 301 and an OLED display panel 302, the controller 301 is coupled to the OLED display panel 302. Wherein the OLED display panel 302 is the same as that in the above embodiment, therefore no additional description is given herebelow. The electronic equipment is used for mobile phone, television, MP3 player, VR glasses and so on.

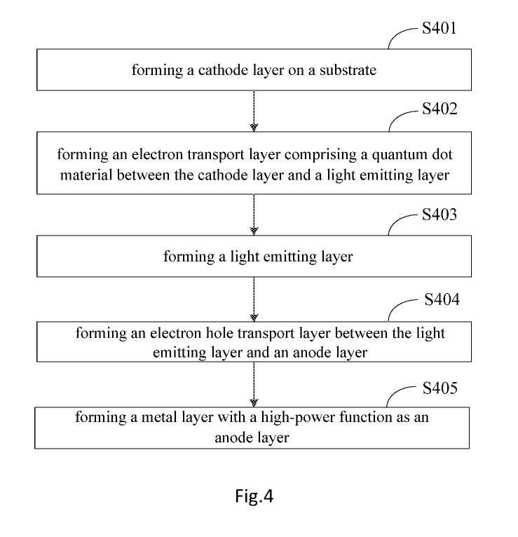

Referring to FIG. 4, FIG. 4 is a flow chart of method of manufacturing an OLED assembly of an embodiment in the present invention. The method comprises:

S401: forming a cathode layer on a substrate.

Wherein, choosing the ITO as the material of the cathode layer, and the cathode layer is formed by magnetron sputtering method. The thickness of the cathode layer is 20 nm to 200 nm, such as 20 nm, 50 nm, 100 nm, 150 nm, 200 nm, and so on. In other embodiments, it may choose other materials to be made of the cathode layer, or the cathode layer may be formed by other method.

S402: forming an electron transport layer comprising a QD material between the cathode layer and a light emitting layer.

Wherein, choosing the ZnO as the material of the electron transport layer, choosing the CdSe as the material of QD to be doped in the electron transport layer, and the electron transport layer was formed by the ink jet printing method. Specifically, preparing the ZnO nano-particle solution and the CdSe QD solution respectively, adding a suitable additive to the above-mentioned solutions to meet the requirements of inkjet printing, a film is formed by the ink jet printing method. The thickness of film of the electron transport layer is 1 nm to 100 nm, such as 1 nm, 10 nm, 40 nm, 70 nm, 100 nm, and so on. In other embodiments, it may choose other materials to be made of the electron transport layer, or the electron transport layer may be formed by other method.

S403: forming a light emitting layer.

Wherein, choosing the poly(9,9-dioctylfluorene) (PFO) as the material of the light emitting layer, and the light emitting layer is formed by ink jet printing method. The thickness of the light emitting layer is 1 nm to 100 nm, such as 1 nm, 15 nm, 50 nm, 80 nm, 100 nm, and so on. In other embodiments, it may choose other materials to be made of the light emitting layer, or the light emitting layer may be formed by other method.

S404: forming an electron hole transport layer between the light emitting layer and an anode layer.

Wherein, choosing the molybdenum oxide (MoO₃) as the material of the electron hole transport layer, and the electron hole transport layer is formed by the vapor deposition method. The thickness of the light emitting layer is 0.5 nm to 50 nm, such as 0.5 nm, 5 nm, 15 nm, 30 nm, 50 nm, and so on. In other embodiments, it may choose other materials to be made of the electron hole transport layer, or the electron hole transport layer may be formed by other method.

S405: forming a metal layer with a high-power function as an anode layer.

Wherein, choosing the silver (Ag) as the material of the anode layer, and the anode layer is formed by the vacuum deposition method. The thickness of the anode layer is 10 nm to 2000 nm, such as 10 nm, 100 nm, 500 nm, 1200 nm, 2000 nm, and so on. In other embodiments, it may choose other materials to be made of the anode layer, or the anode layer may be formed by other method.

In summary, the OLED assembly selects a metal layer with a high-power function as the anode layer, these metals with a high-power function have low chemical activity, can improve the stability of the electrode, thereby extending the life of OLED devices. In addition, the electron transport layer of the OLED assembly is doped with a QD material, and the emission spectrum of the QD light emitting material is concentrated, and the color purity is high, and the color gamut of the OLED display can be improved.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

1. A method of manufacturing an organic light emitting diode assembly, which comprising:
forming a cathode layer on a substrate;
forming an electron transport layer comprising a quantum dot material by the ink jet printing method, on the side of the cathode layer against the substrate;
forming a light emitting layer on the side of the electron transport layer against the cathode layer;
forming an electron hole transport layer on the side of the electron transport layer against the cathode layer;
forming a metal layer with a high-power function as an anode layer by the vacuum deposition method, on the side of the electron hole transport layer against the cathode layer.

2. The method as recited in claim 1, wherein the above-mentioned description of forming a cathode layer on a substrate, which comprises: forming the cathode layer by magnetron sputtering method.

3. The method as recited in claim 1, wherein the thickness of the cathode layer is 20 nm to 200 nm.

4. The method as recited in claim 1, wherein the thickness of the electron transport layer is 1 nm to 100 nm.

5. The method as recited in claim 1, wherein the above-mentioned description of forming a light emitting layer on the side of the electron transport layer against the cathode layer, which comprises: forming the light emitting layer by the ink-jet printing method.

6. The method as recited in claim 1, wherein the thickness of the light emitting layer is 1 nm to 100 nm.

7. The method as recited in claim 1, wherein the above-mentioned description of forming an electron hole transport layer on the side of the electron transport layer against the cathode layer, which comprises: forming the electron hole transport layer by the vapor deposition method.

8. The method as recited in claim 1, wherein the thickness of the electron hole transport layer is 0.5 nm to 50 nm.

9. The method as recited in claim 1, wherein the thickness of the anode layer is 10 nm to 2000 nm.

10. An organic light emitting diode assembly, which comprising an anode layer, an electron hole transport layer, a light emitting layer, an electron transport layer, and a cathode layer arranged sequentially;
wherein the anode layer is a metal layer with a high-power function; and
wherein the electron transport layer comprises a quantum dot material.

11. The assembly as recited in claim 10, wherein the metal layer with a high-power function is a silver layer or a gold layer.

12. The assembly as recited in claim 10, wherein the mass content of the quantum dot material in the electron transport layer is greater than 0 and less than or equal to 20%.

13. The assembly as recited in claim 10, wherein the cathode is a bottom electrode close to the substrate.

14. An organic light emitting diode display panel, which comprising: a substrate, a cover plate, and an organic light emitting diode assembly located between the substrate and the cover plate;
wherein the organic light emitting diode assembly comprises an anode layer, an electron hole transport layer, a light emitting layer, an electron transport layer, and a cathode layer arranged sequentially, and wherein the anode layer is a metal layer with a high-power function, and the electron transport layer comprises a quantum dot material.

15. The display panel as recited in claim 14, wherein the metal layer with a high-power function is a silver or a gold layer.

16. The display panel as recited in claim 14, wherein the mass content of the quantum dot material in the electron transport layer is greater than 0 and less than or equal to 20%.

17. The display panel as recited in claim 14, wherein the cathode is a bottom electrode close to the substrate.
